(19) United States
(12) Patent Application Publication
(10) Pub. No.: US 2025/0196285 A1
(43) Pub. Date: Jun. 19, 2025

(54) Polishing Pad, Method for Producing Polishing Pad, and Method for Polishing Surface of Optical Material or Semiconductor Material

(71) Applicant: FUJIBO Holdings, Inc., Chuo-ku, Tokyo (JP)

(72) Inventors: Teppei TATENO, Ehime (JP); Hiroshi KURIHARA, Ehime (JP); Yamato TAKAMIZAWA, Ehime (JP); Keisuke OCHI, Ehime (JP); Tetsuaki KAWASAKI, Ehime (JP)

(21) Appl. No.: 18/847,793

(22) PCT Filed: Mar. 28, 2023
(86) PCT No.: PCT/JP2023/012363

§ 371 Date: Sep. 17, 2024

(30) Foreign Application Priority Data
Mar. 29, 2022 (JP) 2022-053826

(51) Int. Cl. B24B 37/24

(52) U.S. Cl. CPC B24B 37/24

(57) ABSTRACT

A polishing pad that can suppress the occurrence of scratches, a method for producing the polishing pad, and a method for polishing the surface of an optical material or a semiconductor material using the polishing pad is disclosed. The polishing pad has a polishing layer including microspheres, wherein open pores are present on a surface of the polishing layer. Additionally, in a number fraction-based distribution curve of open pore diameter on a surface of the polishing layer, a peak top is present in a region with an open pore diameter of 15 μm or less, and a number fraction of the open pores at the peak top is 15% or more.

### TECHNICAL FIELD

The present invention relates to a polishing pad, a method for producing the polishing pad, and a method for polishing the surface of an optical material or a semiconductor material. The polishing pad of the present invention is used for polishing optical materials, semiconductor wafers, semiconductor devices, substrates for hard disks, and others, and is suitably used for polishing devices in which oxide layers, metal layers, or other layers are formed on semiconductor wafers in particular.

### BACKGROUND ART

Polishing pads used for polishing semiconductor devices and the like have a polishing layer formed from a synthetic resin such as polyurethane, and voids are formed inside the polishing layer. The voids are open on the surface of the polishing layer, and at the time of polishing, abrasive grains contained in a polishing slurry are retained in the open pores on the surface of the polishing layer, thereby advancing polishing of the object to be polished. One of the known methods to form voids inside the polishing layer is to mix microspheres in the resin, and in recent years, investigations are underway to make the voids (open pores) smaller in diameter or more uniform in order to achieve more precise polishing.

PTL 1 discloses a polishing pad using unexpanded type microspheres with an average particle diameter of 20 to 30 μm.

### CITATION LIST

### Patent Literature

PTL 1: Japanese Patent Laid-Open No. 2010-274362

### SUMMARY OF INVENTION

### Technical Problem

However, the polishing pad using microspheres described in PTL 1 described above has many open pores with a diameter of around 150 μm on the surface of the polishing layer, and polishing debris and the like may remain in these open pores, causing scratches on the workpiece to be polished.

As described above, a polishing pad that can suppress the occurrence of scratches in the workpiece to be polished is desired.

The present invention was made in view of the above problem, and an object thereof is to provide a polishing pad that can suppress the occurrence of scratches in the workpiece to be polished, a method for producing the polishing pad, and a method for polishing the surface of an optical material or a semiconductor material using the polishing pad. Also, another object of the present invention is to provide a polishing pad that can suppress the occurrence of scratches in the workpiece to be polished and exhibits a high polishing rate, a method for producing the polishing pad, and a method for polishing the surface of an optical material or a semiconductor material using the polishing pad.

### Solution to Problem

As a result of diligent researches to solve the above problem, the present inventors have found that the above problem can be solved when the open pores present on the surface of the polishing layer meet particular conditions, and have completed the present invention. Specific aspects of the present invention are as follows.

A polishing pad having a polishing layer comprising microspheres,
wherein open pores are present on a surface of the polishing layer, and
in a number fraction-based distribution curve of open pore diameter on a surface of the polishing layer, a peak top is present in a region with an open pore diameter of 15 μm or less, and a number fraction of the open pores at the peak top is 15% or more.

A polishing pad having a polishing layer comprising microspheres,
wherein open pores are present on a surface of the polishing layer, and
in an open pore circumference×number fraction-based distribution curve of open pore diameter on a surface of the polishing layer, a peak top is present in a region with an open pore diameter of 15 μm or less.

[3] The polishing pad according to [1], wherein a number fraction of the open pores at the peak top is 17% or more.

[4] The polishing pad according to any one of [1] to [3], wherein an average open pore diameter on a surface of the polishing layer is 5 to 20 μm.

[5] The polishing pad according to any one of [1] to [4], wherein the number of the open pores per unit area on a surface of the polishing layer is 1200 to 2500 pores/mm².

[6] The polishing pad according to any one of [1] to [5], wherein an open pore rate on a surface of the polishing layer is 10 to 50%.

[7] The polishing pad according to any one of [1] to [6], wherein the polishing layer further comprises a polyurethane resin.

[8] The polishing pad according to any one of [1] to [7], wherein the polyurethane resin is a cured product of a curable resin composition comprising an isocyanate-terminated urethane prepolymer, a curing agent, and thermoexpandable microspheres.

[9] A method for producing a polishing pad having a polishing layer comprising microspheres, the method comprising:
(a) a step of preparing a curable resin composition comprising thermoexpandable microspheres with an average particle diameter (D50) of 1 to 20 μm; and
(b) a step of heating the curable resin composition under heating conditions including a temperature rise condition of 1.5 to 7.5° C./min to cure the curable resin composition, thereby forming the polishing layer, and to expand the thermoexpandable microspheres, thereby forming the microspheres.

The method for producing a polishing pad according to [9], wherein the polishing pad is the polishing pad according to any one of [1] to [8].

A method for polishing a surface of an optical material or a semiconductor material, the method comprising a step of polishing a surface of an optical material or a semiconductor material using the polishing pad according to any one of [1] to [8].

The polishing pad according to any one of [2] to [8], wherein, in a number fraction-based distribution curve of open pore diameter on a surface of the polishing layer, a peak top is present in a region with an open pore diameter of 15 μm or less, and a number fraction of the open pores at the peak top is 15% or more.

The polishing pad according to any one of [1] to [8] and [12], wherein, in a number fraction-based distribution curve of open pore diameter on a surface of the polishing layer, a total value (integrated value) of a number fraction of open pores present in a region with an open pore diameter of 15 μm or less is 55 to 90%.

The polishing pad according to any one of [1] to [8], [12], and [13], wherein, in a number fraction-based distribution curve of open pore diameter on a surface of the polishing layer, a total value (integrated value) of a number fraction of open pores present in a region with an open pore diameter of 20 μm or less is 80 to 90%.

The polishing pad according to any one of [1] to [8] and to [14], wherein, in an open pore circumference×number fraction-based distribution curve of open pore diameter on a surface of the polishing layer, a peak top is present in a region with an open pore diameter of 15 μm or less, and an open pore circumference×number fraction at the peak top is 12 μm·% or more.

The polishing pad according to any one of [1] to [8] and to [15], wherein, in an open pore circumference×number fraction-based distribution curve of open pore diameter on a surface of the polishing layer, a total value (integrated value) of an open pore circumference×number fraction of open pores present in a region with an open pore diameter of 15 μm or less is 40 to 75 μm·%.

The polishing pad according to any one of [1] to [8] and to [16], wherein, in an open pore circumference×number fraction-based distribution curve of open pore diameter on a surface of the polishing layer, a total value (integrated value) of an open pore circumference×number fraction of open pores present in a region with an open pore diameter of 20 μm or less is 60 to 90 μm·%.

The method for producing a polishing pad according to [9], wherein the polishing pad is the polishing pad according to any one of to [17].

A method for polishing a surface of an optical material or a semiconductor material, the method comprising a step of polishing a surface of an optical material or a semiconductor material using the polishing pad according to any one of to [17].

### (Definition)

In the present specification, when a numerical range is expressed by using “X to Y”, the range shall include X and Y, the numerical values at both ends of the range.

In the present specification, “peak” in the distribution curve of open pore diameter refers to the portion of the distribution curve that is mountainous when viewed in its entirety. In the distribution curve, a large mountainous portion may contain small mountainous portions, but such small mountainous portions are not included in the “peak” herein.

In the present specification, “peak top” in the distribution curve of open pore diameter refers to the vertex portion of the above-mentioned peak.

In the present specification, “number fraction” of open pores in the distribution curve of open pore diameter means the proportion (%) of the number of open pores having the relevant open pore diameter (when the open pore diameter is expressed in a numerical range, the total number of open pores included in that numerical range) to the total number of open pores.

In the present specification, “open pore circumference” in the distribution curve of open pore diameter means the length of the circumference of an open pore when it is considered as a circle, and can be calculated by the diameter of the relevant open pore (open pore diameter)×circular constant.

### Advantageous Effects of Invention

A polishing pad of the present invention can suppress the occurrence of scratches in the workpiece to be polished.

### BRIEF DESCRIPTION OF DRAWINGS

FIG. 1 is a graph showing the heating conditions when forming the polishing layer in Examples 1 to 3 and Comparative Examples 1 and 2.

FIG. 2 is a graph showing a distribution curve of open pore diameter-number fraction on the surface of the polishing layer of Example 1.

FIG. 3 is a graph showing a distribution curve of open pore diameter-number fraction on the surface of the polishing layer of Example 2.

FIG. 4 is a graph showing a distribution curve of open pore diameter-number fraction on the surface of the polishing layer of Example 3.

FIG. 5 is a graph showing a distribution curve of open pore diameter-number fraction on the surface of the polishing layer of Comparative Example 1.

FIG. 6 is a graph showing a distribution curve of open pore diameter-number fraction on the surface of the polishing layer of Comparative Example 2.

FIG. 7 is a graph showing a distribution curve of open pore diameter-open pore circumference×number fraction on the surface of the polishing layer of Example 1.

FIG. 8 is a graph showing a distribution curve of open pore diameter-open pore circumference×number fraction on the surface of the polishing layer of Example 2.

FIG. 9 is a graph showing a distribution curve of open pore diameter-open pore circumference×number fraction on the surface of the polishing layer of Example 3.

FIG. 10 is a graph showing a distribution curve of open pore diameter-open pore circumference×number fraction on the surface of the polishing layer of Comparative Example 1.

FIG. 11 is a graph showing a distribution curve of open pore diameter-open pore circumference×number fraction on the surface of the polishing layer of Comparative Example 2.

### DESCRIPTION OF EMBODIMENTS

### (Action)

As a result of diligent researches on the relationship between open pores on the surface of the polishing layer and scratches on the workpiece to be polished, the present inventors have unexpectedly found that scratches on the workpiece to be polished can be suppressed when, in a number fraction-based distribution curve of open pore diameter, a peak top is present in a region with an open pore diameter of 15 μm or less and the number fraction of the open pores at the peak top is 15% or more, and/or when, in an open pore circumference×number fraction-based distribution curve of open pore diameter, a peak top is present in a region with an open pore diameter of 15 μm or less. The details of why such a characteristic is obtained are not clear, but are inferred as follows.

The present inventors thought that the scratches on the workpiece to be polished are caused by the edges of the open pores (the boundary between the hollow (open pore) portion where the polishing layer component is not present and the solid portion where the polishing layer component is present). In this case, it is considered that open pores with a large diameter present on the surface of the polishing layer are likely to cause scratches due to their long edge lengths, while open pores with a small diameter are unlikely to cause scratches due to their short edge lengths. Therefore, it is considered that scratches can be suppressed by increasing the proportion of open pores with a small diameter among all open pores.

In a number fraction-based distribution curve of open pore diameter on the surface of the polishing layer, it can be said that the region with an open pore diameter of 15 μm or less indicates a region corresponding to open pores with a small diameter, and it can be assumed that scratches can be suppressed when a peak top is present in that region and the number fraction of the open pores at that peak top is relatively large, 15% or more.

In addition, in open pores with a particular diameter, by multiplying the open pore circumference (the length of the circumference of an open pore when it is considered as a circle) by the number fraction of open pores, the length of the edge in open pores with a particular diameter can be weighted for expression. By using such an open pore circumference×number fraction to create a distribution curve of open pore diameter, the relationship between scratches and open pore edges can be more directly expressed. In an open pore circumference×number fraction-based distribution curve of open pore diameter, it can be said that a peak top present in a region with an open pore diameter of 15 μm or less means that there is a relatively large number of open pores with a short edge length, and it can thus be assumed that scratches can be suppressed.

Hereinafter, a polishing pad of the present invention, a method for producing the polishing pad, and a method for polishing the surface of an optical material or a semiconductor material will be described.

### 1. Polishing pad

### First Embodiment

A polishing pad according to the first embodiment of the present invention is
a polishing pad having a polishing layer including microspheres,
wherein open pores are present on a surface of the polishing layer, and
in a number fraction-based distribution curve of open pore diameter on the surface of the polishing layer, a peak top is present in a region with an open pore diameter of 15 μm or less, and the number fraction of the open pores at the peak top is 15% or more.

### (1) Microspheres

By mixing the microspheres into the components constituting the polishing layer (such as polyurethane resin), a foamed product can be formed. The microspheres are not particularly limited, and examples thereof include unexpanded thermoexpandable microspheres composed of an outer shell (polymer shell) composed of a thermoplastic resin and a low boiling point hydrocarbon encapsulated in that outer shell, spheres formed by thermally expanding such unexpanded thermoexpandable microspheres, or a combination thereof.

The average particle diameter (D50, median diameter) of the above unexpanded thermoexpandable microspheres in an unexpanded state is not particularly limited, but it is preferably 1 to 20 μm, more preferably 3 to 15 μm, and most preferably 6 to 10 μm. The above numerical value range allows the average open pore diameter on the surface of the polishing layer to be 20 μm or less, even when the above thermoexpandable microspheres are expanded, enabling more precise polishing of the workpiece to be polished. The above average particle diameter (D50, median diameter) can be measured using a laser diffraction particle size distribution measuring apparatus (for example, manufactured by Spectris plc, Mastersizer 2000).

The expansion initiation temperature of the above unexpanded thermoexpandable microspheres is not particularly limited, but from the viewpoint of heat of reaction due to the polymerization reaction of the prepolymer or the like, it is preferably 50 to 200° C., more preferably 80 to 150° C., and most preferably 90 to 120° C.

The maximum expansion temperature of the above unexpanded thermoexpandable microspheres is not particularly limited, but from the viewpoint of heat of reaction due to the polymerization reaction of the prepolymer or the like, it is preferably 90 to 200° C., more preferably 110 to 170° C., and most preferably 120 to 150° C.

As the polymer that forms the above polymer shell, thermoplastic resins, such as polyvinyl alcohol, polyvinyl pyrrolidone, poly(meth)acrylic acid, polyacrylamide, polyethylene glycol, polyhydroxy ether acrylite, maleic acid copolymers, polyethylene oxide, polyurethane, poly(meth)acrylonitrile, polyvinylidene chloride, polyvinyl chloride, and organic silicone-based resins, as well as copolymers in which two or more of the monomers constituting these resins are combined (for example, acrylonitrile-vinylidene chloride copolymer, acrylonitrile-methyl methacrylate copolymer, vinyl chloride-ethylene copolymer, and the like), can be used. Among these, in terms of achieving the effect of the present application, it is preferable to use an acrylonitrile-methyl methacrylate copolymer.

Also, as the low boiling point hydrocarbon encapsulated in the polymer shell, for example, isobutane, pentane, isopentane, petroleum ether, or a combination of two or more types among them can be used.

The content of the microspheres relative to the entire polishing layer or the entire cured product of the curable resin composition described below is not particularly limited, but it is preferably 0.1 to 10.0% by weight, more preferably 1.0 to 5.0% by weight, and most preferably 2.0 to 4.0% by weight. When the content of the microspheres is within the above numerical range, the density of the polishing layer is made uniform.

### (2) Open Pores

In the first embodiment of the present invention, the features of the open pores are specified based on a number fraction-based distribution curve of open pore diameter on the surface of the polishing layer. As the number fraction-based distribution curve of open pore diameter on the surface of the polishing layer, a distribution curve can be used in which the horizontal axis is the open pore diameter and the vertical axis is the proportion of the number of open pores relative to the total number of open pores (number fraction).

The above distribution curve can be obtained based on the procedures and conditions described in item (2) of (Evaluation methods) in [Examples] described below.

In the above distribution curve according to the first embodiment, the upper limit of the open pore diameter in the region where the peak top is present is 15 μm or less, and can be 14 μm or less, 13 μm or less, or 12 μm or less. The lower limit of the open pore diameter in the region where the peak top is present is not particularly limited, but it can be 6 μm or more, 7 μm or more, or 8 μm or more. For the open pore diameter in the region where the peak top is present, the above upper limits and lower limits can be arbitrarily combined.

In the above distribution curve according to the first embodiment, the lower limit of the above number fraction of the open pores at the peak top is 15% or more, and can be 16% or more, 17% or more, 18% or more, or 19% or more. The upper limit of the above number fraction of the open pores at the peak top is not particularly limited, but it can be 30% or less or 25% or less. For the above number fraction of the open pores at the peak top, the above upper limits and lower limits can be arbitrarily combined.

For the polishing pad according to the first embodiment of the present invention, the occurrence of scratches on the workpiece to be polished can be suppressed when, in the above distribution curve, the open pore diameter in the region where the peak top is present is 15 μm or less and the number fraction of the open pores at the peak top is 15% or more.

Open pores on the surface of the polishing layer having such features can be formed by using particular unexpanded thermoexpandable microspheres and expanding them under particular heating conditions, as in Examples 1 to 3, described below, for example.

In the above distribution curve according to the first embodiment, the number of the above peak top is not particularly limited, but it is preferably one.

In the above distribution curve according to the first embodiment, the total value (integrated value) of the number fraction of open pores present in a region with an open pore diameter of 15 μm or less is not particularly limited, but it can be 55 to 90%, 60 to 85%, or 70 to 80%. Also, the total value (integrated value) of the number fraction of open pores present in a region with an open pore diameter of 20 μm or less is not particularly limited, but it can be 75 to 95% or 80 to 90%.

In the first embodiment, the average open pore diameter on the surface of the polishing layer is not particularly limited, but it is preferably 5 to 20 μm, more preferably 8 to 18 μm, and most preferably 10 to 15 μm. When the average open pore diameter is within the above numerical range, the workpiece to be polished can be polished more precisely.

In the first embodiment, the number of the open pores per unit area on the surface of the polishing layer is not particularly limited, but it is preferably 1200 to 2500 pores/mm², more preferably 1500 to 2500 pores/mm², and most preferably 1600 to 2000 pores/mm².

In the first embodiment, the open pore rate on the surface of the polishing layer is not particularly limited, but it is preferably 10 to 50%, more preferably 15 to 45%, and most preferably 20 to 40%. When the open pore rate is within the above numerical range, the slurry is retained well and the workpiece to be polished can be polished stably. Here, the open pore rate on the surface of the polishing layer means the proportion (%) of the total area of open pores present on the surface of the polishing layer relative to the area of the surface of the polishing layer.

The above average open pore diameter, number of the open pores per unit area, and open pore rate on the surface of the polishing layer can be measured based on the procedures and conditions described in item (2) of (Evaluation methods) in [Examples] described below.

In the first embodiment, the density of the polishing layer is not particularly limited, but it is preferably 0.60 to 0.95 g/cm³, more preferably 0.65 to 0.90 g/cm³, and most preferably 0.70 to 0.85 g/cm³. When the density is within the above numerical range, the occurrence of scratches caused by polishing by-products (polishing debris) can be suppressed.

In the first embodiment, the Shore D hardness of the polishing layer is not particularly limited, but it is preferably 35 to 75, more preferably 40 to 70, and most preferably 45 to 65. When the Shore D hardness is too small, it is difficult to flatten minor asperities. When the Shore D hardness is too large, scratches may occur on the workpiece to be polished.

The above density and Shore D hardness of the polishing layer can be measured based on the procedures and conditions described in item (1) of (Evaluation methods) in [Examples] described below.

The polishing pad of the present invention has a polishing layer. The polishing layer is disposed at a position in direct contact with a material to be polished, while other portions of the polishing pad may be constituted by a material for supporting the polishing pad, for example, a material that is rich in elasticity, such as rubber. Depending on the rigidity of the polishing pad, the polishing layer can be used as the polishing pad.

The polishing pad of the present invention does not greatly differ in shape from general polishing pads except that it can suppress the occurrence of scratches, and can be used in the same manner as general polishing pads. For example, it is possible to perform polishing by pressing the polishing layer against the material to be polished while rotating the polishing pad, or it is possible to perform polishing by pressing the material to be polished against the polishing layer while rotating the material to be polished.

The polishing pad of the present invention can be produced by generally known production methods such as mold molding and slab molding. It is produced as follows: at first, a block of polyurethane resin or the like is formed by the above production methods, and the block is sliced into a sheet to mold a polishing layer, which is then pasted to a support or other material. Alternatively, the polishing layer can be molded directly on the support.

More specifically, the polishing layer becomes a polishing pad by attaching double-sided tape to the side opposite to the polishing surface of the polishing layer and cutting it into a predetermined shape. There is no particular restriction on the double-sided tape, and any double-sided tape known in the art can be arbitrarily selected for use. In addition, the polishing pad may have a single layer structure composed only of the polishing layer, or it may be composed of multiple layers with other layers (underlayer and support layer) pasted to the side opposite to the polishing surface of the polishing layer.

The polishing layer can further include a polyurethane resin.

The above polyurethane resin is not particularly limited, but it can be a cured product of a curable resin composition containing an isocyanate-terminated urethane prepolymer, a curing agent, and thermoexpandable microspheres.

The polishing layer can be molded by preparing a curable resin composition containing an isocyanate-terminated urethane prepolymer, a curing agent, and thermoexpandable microspheres, and foaming and curing the curable resin composition.

The curable resin composition can be, for example, a two-component composition prepared by mixing liquid A containing an isocyanate-terminated urethane prepolymer and liquid B containing a curing agent component. The other components may be added to liquid A or may be added to liquid B, but in the case where problems arise, it can be a composition constituted by further dividing the components into multiple liquids and mixing three or more liquids.

### (3) Isocyanate-Terminated Urethane Prepolymer

The above isocyanate-terminated urethane prepolymer can be a product obtained by allowing a polyol component to react with a polyisocyanate component.

### (Polyol Component)

As the polyol component, a low molecular weight polyol, a high molecular weight polyol, or a combination thereof can be used. In the present specification, the low molecular weight polyol is a polyol having a number average molecular weight of 30 to 300, and the high molecular weight polyol is a polyol having a number average molecular weight of greater than 300.

The number average molecular weight of the above high molecular weight polyol and the above low molecular weight polyol can be measured as the molecular weight in terms of polyethylene glycol/polyethylene oxide (PEG/PEO) based on gel permeation chromatography (GPC) under the following conditions.

### <Measurement Conditions>

Column: Ohpak SB-802.5 HQ (exclusion limit 10000)+SB-803 HQ (exclusion limit 100000)
Mobile phase: 5 mM LiBr/DMF
Flow rate: 0.3 ml/min (26 kg/cm²)
Oven: 60° C.
Detector: RI 40° C.
Sample volume: 20 μl

Examples of the above low molecular weight polyol include ethylene glycol, diethylene glycol, triethylene glycol, 1,2-propanediol, 1,3-propanediol, 1,3-butanediol, 1,4-butanediol, neopentyl glycol, pentanediol, 3-methyl-1,5-pentanediol, 1,6-hexanediol, or a combination of two or more types among thereof.

Examples of the above high molecular weight polyol include:
a polyether polyol such as polytetramethylene ether glycol (PTMG), polyethylene glycol, or
polypropylene glycol:
a polyester polyol such as a reaction product of ethylene glycol and adipic acid or a reaction
product of butylene glycol and adipic acid:
a polycarbonate polyol:
a polycaprolacton polyol: or
a combination of two or more types among them.

### (Polyisocyanate Component)

Examples of the polyisocyanate component include:
m-phenylene diisocyanate;
p-phenylene diisocyanate;
2,6-tolylene diisocyanate (2,6-TDI);
2,4-tolylene diisocyanate (2,4-TDI);
naphthalene-1,4-diisocyanate;
diphenylmethane-4,4′-diisocyanate (MDI);
4,4′-methylene-bis(cyclohexyl isocyanate) (hydrogenated MDI);
3,3′-dimethoxy-4,4′-biphenyl diisocyanate;
3,3′-dimethyldiphenylmethane-4,4′-diisocyanate;
xylylene-1,4-diisocyanate;
4,4′-diphenylpropane diisocyanate;
trimethylene diisocyanate;
hexamethylene diisocyanate;
propylene-1,2-diisocyanate;
butylene-1,2-diisocyanate;
cyclohexylene-1,2-diisocyanate;
cyclohexylene-1,4-diisocyanate;
p-phenylene diisothiocyanate;
xylylene-1,4-diisothiocyanate;
ethylidyne diisothiocyanate; or
a combination of two or more types among them.

Among these, from the viewpoint of polishing characteristics, it is preferable to use tolylene diisocyanate such as 2,6-tolylene diisocyanate (2,6-TDI) and 2,4-tolylene diisocyanate (2,4-TDI).

The NCO equivalent (g/eq) of the isocyanate-terminated urethane prepolymer is preferably less than 600, more preferably 350 to 550, and most preferably 400 to 500. When the NCO equivalent (g/eq) is within the above numerical range, the polishing layer can exhibit appropriate hardness. Note that the NCO equivalent (g/eq) is determined as “(parts by mass of polyisocyanate compound+parts by mass of polyol compound)/[(number of functional groups per molecule of polyisocyanate compound×parts by mass of polyisocyanate compound/molecular weight of polyisocyanate compound)−(number of functional groups per molecule of polyol compound×parts by mass of polyol compound/molecular weight of polyol compound)]”, and is a numerical value indicating the molecular weight of prepolymer per NCO group.

### (4) Curing Agent

Examples of the curing agent contained in the curable resin composition include an amine curing agent, which will be described below.

Examples of the polyamine that constitutes the amine curing agent include a diamine, and examples thereof include an alkylenediamine such as ethylenediamine, propylenediamine, or hexamethylenediamine: a diamine having an aliphatic ring such as isophoronediamine or dicyclohexylmethane-4,4′-diamine; a diamine having an aromatic ring such as 3,3′-dichloro-4,4′-diaminodiphenylmethane (another name: methylenebis-o-chloroaniline) (hereinafter, abbreviated as MOCA); a diamine having a hydroxy group, in particular, a hydroxyalkylalkylenediamine, such as 2-hydroxyethylethylenediamine, 2-hydroxyethylpropylenediamine, di-2-hydroxyethylethylenediamine, di-2-hydroxyethylpropylenediamine, 2-hydroxypropylethylenediamine, or di-2-hydroxypropylethylenediamine; or a combination of two or more types among them. In addition, it is also possible to use a tri-functional triamine compound and a tetra- or higher-functional polyamine compound.

The particularly preferred amine curing agent is the above-mentioned MOCA, and the chemical structure of this MOCA is as follows.

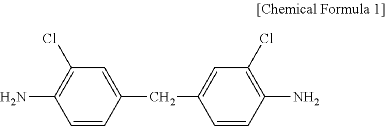 [SMILES: Nc1ccc(Cc2ccc(N)c(Cl)c2)cc1Cl]

As for the amount of the entire curing agent, an amount is used that provides a ratio of the number of moles of an active hydrogen group (such as NH₂) in the curing agent to the number of moles of NCO in the isocyanate-terminated urethane prepolymer (number of moles of active hydrogen group/number of moles of NCO) of preferably 0.70 to 1.10, more preferably 0.80 to 1.00, and most preferably 0.85 to 0.95.

### (5) Other Components

In addition, it is also possible to add a catalyst or others commonly used in the art to the curable resin composition.

It is also possible to add the above-mentioned polyisocyanate component to the curable resin composition later, and the weight proportion of the additional polyisocyanate component relative to the total weight of the isocyanate-terminated urethane prepolymer and the additional polyisocyanate component is preferably 0.1 to 10.0% by weight, more preferably 0.5 to 8.0% by weight, and particularly preferably 1.0 to 5.0% by weight.

As the polyisocyanate component to be additionally added to the polyurethane resin curable composition, the above-mentioned polyisocyanate components can be used without particular limitation, but 4,4′-methylene-bis(cyclohexyl isocyanate) (hydrogenated MDI) is preferred.

### Second Embodiment

A polishing pad according to the second embodiment of the present invention is
a polishing pad having a polishing layer including microspheres,
wherein open pores are present on the surface of the polishing layer, and
in an open pore circumference×number fraction-based distribution curve of open pore diameter on the surface of the polishing layer, a peak top is present in a region with an open pore diameter of 15 μm or less.

### (1) Microspheres

By mixing the microspheres into the components constituting the polishing layer (such as polyurethane resin), a foamed product can be formed.

Each configuration, such as the type, features, and content of the microspheres, is not particularly limited, and it can be the same as each configuration, such as the type, features, and content of the microspheres described in the above-mentioned first embodiment.

### (2) Open Pores

In the second embodiment of the present invention, the features of the open pores are specified based on an open pore circumference×number fraction-based distribution curve of open pore diameter on the surface of the polishing layer. As the open pore circumference×number fraction-based distribution curve of open pore diameter on the surface of the polishing layer, a distribution curve can be used in which the horizontal axis is the open pore diameter and the vertical axis is the open pore circumference×number fraction.

The above distribution curve can be obtained based on the procedures and conditions described in item (2) of (Evaluation methods) in [Examples] described below.

The polishing pad according to the second embodiment of the present invention can have, together with the features of the open pores based on the above-mentioned open pore circumference×number fraction-based distribution curve of open pore diameter on the surface of the polishing layer, the features of the open pores based on the number fraction-based distribution curve of open pore diameter on the surface of the polishing layer, as mentioned in the above first embodiment, as well.

In the above distribution curve according to the second embodiment, the upper limit of the open pore diameter in the region where the peak top is present is 15 μm or less, and can be 14 μm or less or 13 μm or less. The lower limit of the open pore diameter in the region where the peak top is present is not particularly limited, but it can be 6 μm or more, 7 μm or more, or 8 μm or more. For the open pore diameter in the region where the peak top is present, the above upper limits and lower limits can be arbitrarily combined.

In the above distribution curve according to the second embodiment, the lower limit of the above open pore circumference×number fraction at the peak top is not particularly limited, but it can be 10 μm·% or more, 11 μm·% or more, 12 μm·% or more, or 13 μm·% or more. The upper limit of the above open pore circumference×number fraction at the peak top is not particularly limited, but it can be 20 μm. % or less or 18 μm. % or less. For the above open pore circumference×number fraction at the peak top, the above upper limits and lower limits can be arbitrarily combined.

For the polishing pad according to the second embodiment of the present invention, the occurrence of scratches on the workpiece to be polished can be suppressed when, in the above distribution curve, the open pore diameter in the region where the peak top is present is 15 μm or less.

Open pores on the surface of the polishing layer having such features can be formed by using particular unexpanded thermoexpandable microspheres and expanding them under particular heating conditions, as in Examples 1 to 3, described below, for example.

In the above distribution curve according to the second embodiment, the number of the above peak top is not particularly limited, but it is preferably one.

In the above distribution curve according to the second embodiment, the total value (integrated value) of the open pore circumference×number fraction of open pores present in a region with an open pore diameter of 15 μm or less is not particularly limited, but it can be 30 to 80 μm·%, 40 to 75 μm·%, or 50 to 70 μm·%. Also, the total value (integrated value) of the open pore circumference×number fraction of open pores present in a region with an open pore diameter of 20 μm or less is not particularly limited, but it can be 60 to 90 μm·% or 70 to 85 μm·%.

In the second embodiment, each feature, such as the average open pore diameter, number of the open pores per unit area, and open pore rate on the surface of the polishing layer, can be the same as each feature, such as the average open pore diameter, number of the open pores per unit area, and open pore rate described in the above-mentioned first embodiment.

In the second embodiment, each feature, such as the density and Shore D hardness of the polishing layer and the method for forming the polishing pad, can be the same as the features described in the above-mentioned first embodiment.

The polishing layer can further include a polyurethane resin.

The above polyurethane resin is not particularly limited, but it can be a cured product of a curable resin composition containing an isocyanate-terminated urethane prepolymer, a curing agent, and thermoexpandable microspheres.

In the second embodiment, each feature, such as the type, content, and other properties of the isocyanate-terminated urethane prepolymer, polyol component, polyisocyanate component, curing agent, and other components, can be the same as the features described in the above-mentioned first embodiment.

### 2. Method for Producing Polishing Pad

A method for producing a polishing pad of the present invention is a method for producing a polishing pad having a polishing layer including microspheres, the method including:
(a) a step of preparing a curable resin composition containing thermoexpandable microspheres with an average particle diameter (D50) of 1 to 20 μm; and
(b) a step of heating the curable resin composition under heating conditions including a temperature rise condition of 1.5 to 7.5° C./min to cure the curable resin composition, thereby forming the polishing layer, and to expand the thermoexpandable microspheres, thereby forming the microspheres.

The average particle diameter (D50) of the above thermoexpandable microspheres is 1 to 20 μm, more preferably 3 to 15 μm, and most preferably 6 to 10 μm.

Each feature, such as the type, expansion initiation temperature, and maximum expansion temperature of the above thermoexpandable microspheres, can be the same as each feature of the unexpanded thermoexpandable microspheres mentioned in the above first embodiment.

Step (a) can include a step of mixing the above thermoexpandable microspheres, isocyanate-terminated urethane prepolymer, and curing agent. The above isocyanate-terminated urethane prepolymer and curing agent can be the same as the isocyanate-terminated urethane prepolymer and curing agent mentioned in the above first embodiment.

Step (b) can be performed inside a mold. In this case, the method for producing a polishing pad can further include, between step (a) and step (b), a step of pouring the curable resin composition obtained in step (a) into a mold (pouring step). In order to prevent the curable resin composition from being cured before pouring, it is preferable to set the temperature of the mold during the pouring step to 130° C. or lower, 100° C. or lower, or 90° C. or lower.

The temperature (or mold temperature) at the time of initiating step (b) (or at the time of completing the pouring) is not particularly limited, but in order to suppress excessive expansion of the thermoexpandable microspheres, it is preferably 75 to 140° C., 75 to 120° C., or 75 to 100° C., and it can be 75 to 95° C. or 75 to 92° C.

The temperature rise condition (temperature rise rate) at the time of heating in step (b) is 1.5 to 7.5° C./min, and it can be 4.0 to 7.5° C./min, 6.0 to 7.5° C./min, or 7.0 to 7.5° C./min. When the temperature rise condition (temperature rise rate) is within the above numerical range, the average particle diameter of the thermoexpandable microspheres can be controlled in the range that achieves the effect of the present application. The above temperature rise rate means the average temperature rise rate in a temperature rise over a particular period of time.

The above temperature rise rate can be employed for a period of 2 to 10 minutes, 2 to 7 minutes, or 2 to 5 minutes, with the initiation of step (b) or the completion of the pouring as 0 minutes.

The temperature rise in step (b) can be performed over a period of 0 to 20 minutes, 0 to 15 minutes, or 0 to 10 minutes, with the initiation of step (b) or the completion of the pouring as 0 minutes.

The temperature after the temperature rise of the curable resin composition in step (b) can be 100 to 160° C., 100 to 140° C., 110 to 135° C., or 120 to 130° C. The temperature after the temperature rise can be maintained over a period of 5 to 60 minutes, 5 to 40 minutes, 10 to 30 minutes, or 10 to 20 minutes, with the initiation of step (b) or the completion of the pouring as 0 minutes.

As in Examples 1 to 3 described below, step (b) can be a step of primary curing performed inside a mold, and after such a step of primary curing, the formed resin foamed product can be removed from the mold and that resin foamed product can be subjected to secondary curing. Even in this case, since the open pores of the resulting polishing pad are formed in step (b) (primary curing), the conditions in step (b) mainly determine the features of the open pores of the polishing pad.

By the method for producing a polishing pad of the present invention, the polishing pad according to the above-mentioned first embodiment or second embodiment can be obtained.

### 3. Method for Polishing Surface of Optical Material or Semiconductor Material

In the present invention, a method for polishing the surface of an optical material or a semiconductor material includes a step of polishing the surface of an optical material or a semiconductor material using the polishing pad according to the above-mentioned first embodiment or second embodiment.

In some embodiments of the present invention, the method for polishing the surface of an optical material or a semiconductor material can further include a step of supplying slurry to the surface of the polishing pad, the surface of the optical material or the semiconductor material, or both of them.

### (Slurry)

The liquid component contained in the slurry is not particularly limited, examples of which include water (pure water), an acid, an alkali, an organic solvent, or a combination thereof, and it is selected according to the material of the workpiece to be polished, the desired polishing conditions, and other factors. It is preferable for the slurry to be composed mainly of water (pure water), and preferable to contain 80% by weight or more of water relative to the entire slurry. The abrasive grain component contained in the slurry is not particularly limited, examples of which include silica, zirconium silicate, cerium oxide, aluminum oxide, manganese oxide, or a combination thereof. The slurry may contain other components such as an organic matter that is soluble in the liquid component and a pH adjuster.

### EXAMPLES

The present invention will be described experimentally by means of the following examples, but the following description is not intended to be construed as limiting the scope of the present invention to the following examples.

### (Materials)

The materials used in Examples 1 to 3 and Comparative Examples 1 and 2, described below, are listed below.
Isocyanate-terminated urethane prepolymer:

Prepolymer (1) . . . . Urethane prepolymer with an NCO equivalent of 455, including 2,4-tolylene diisocyanate as the polyisocyanate component, including a polytetramethylene ether glycol with a number average molecular weight of 650 and a polytetramethylene ether glycol with a number average molecular weight of 1000 as the high molecular weight polyol components, and including diethylene glycol as the low molecular weight polyol component
Curing agent:

MOCA . . . 3,3′-Dichloro-4,4′-diaminodiphenylmethane (another name: methylenebis-o-chloroaniline) (MOCA) (NH₂ equivalent=133.5)
Microspheres:

Microspheres (1) . . . . Matsumoto Microsphere (Registered Trademark) FN-80GSD (manufactured by Matsumoto Yushi-Seiyaku Co., Ltd.) (unexpanded type, average particle diameter (D50) in an unexpanded state: 6 to 10 μm, expansion initiation temperature: 100 to 110° C., maximum expansion temperature: 125 to 135° C., shell composition: acrylonitrile-methyl methacrylate copolymer)

Microspheres (2) . . . . Expancel (Registered Trademark) 461DU20 (manufactured by Japan Fillite Co., Ltd.) (unexpanded type, average particle diameter (D50) in an unexpanded state: 6 to 9 μm, expansion initiation temperature: 100 to 106° C., maximum expansion temperature: 143 to 151° C., shell composition: acrylonitrile-vinylidene chloride copolymer)

Microspheres (3) . . . . Matsumoto Microsphere (Registered Trademark) HF-48D (manufactured by Matsumoto Yushi-Seiyaku Co., Ltd.) (unexpanded type, average particle diameter (D50) in an unexpanded state: 9 to 15 μm, expansion initiation temperature: 90 to 100° C., maximum expansion temperature: 125 to 135° C., shell composition: acrylonitrile-methyl methacrylate copolymer)

Microspheres (4) . . . . Expancel (Registered Trademark) 920DU20 (manufactured by Japan Fillite Co., Ltd.) (unexpanded type, average particle diameter (D50) in an unexpanded state: 5 to 9 μm, expansion initiation temperature: 120 to 145° C., maximum expansion temperature: 155 to 175° C., shell composition: acrylonitrile-methyl methacrylate copolymer)

### Example 1

100 g of prepolymer (1) as component A, 26.3 g of MOCA, which is a curing agent, as component B, and 3.5 g of microspheres (1) as component C were prepared. Note that, although each component is listed as a g indication to show the ratio thereof, it is only required to prepare the necessary weight (parts) depending on the size of the block. Hereinafter, the g (parts) indication will be used in the same manner.

Component A and component C were mixed, and the obtained mixture of component A and component C was defoamed under reduced pressure. MOCA, which is component B, was also defoamed under reduced pressure. The defoamed mixture of component A and component C and the defoamed component B were supplied to a mixing machine to obtain a mixed solution of component A, component B, and component C.

Note that the ratio of the number of moles of NH₂ in MOCA of component B to the number of moles of NCO in prepolymer (1) of component A (number of moles of NH₂/number of moles of NCO) in the obtained mixed solution of component A, component B, and component C is 0.9. Also, the content of microspheres (1), which are component C, relative to the entire mixed solution above, is 2.7% by weight.

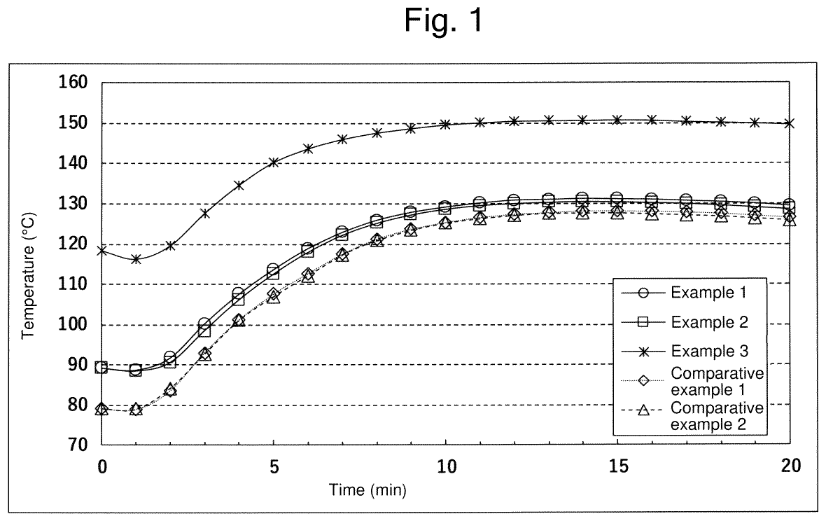

The obtained mixed solution of component A, component B, and component C was poured into a mold form (850 mm×850 mm square shape) that had been heated to 90° C. Heating and temperature rise were performed for a period of 2 to 10 minutes such that the average temperature rise rate in 2 to 5 minutes from the completion of the pouring was 7.3° C./min, and the temperature after 10 minutes from the completion of the pouring was set to 130° C. Thereafter, the temperature was maintained at 130° C. for 10 to 20 minutes from the completion of the pouring to perform primary curing. The relationship between time from the completion of the pouring and temperature in the primary curing is shown in FIG. 1. The formed resin foamed product was removed from the mold form and allowed to undergo secondary curing in an oven at 120° C. for 4 hours. The obtained resin foamed product was allowed to cool down to 25° C. and then heated again in an oven at 120° C. for 5 hours. The obtained resin foamed product was sliced into thickness of 1.3 mm over the thickness direction to produce a urethane sheet, and double-sided tape was attached to the back side of this urethane sheet to obtain a polishing pad.

### Example 2

A urethane sheet was produced in the same manner as in Example 1 to obtain a polishing pad of Example 2, except that the amount of microspheres (1), component C of Example 1, used was changed from 3.5 g to 2.7 g. The relationship between time from the completion of the pouring and temperature in the primary curing is the same as in Example 1, as shown in FIG. 1.

Note that the ratio of the number of moles of NH₂ in MOCA of component B to the number of moles of NCO in prepolymer (1) of component A (number of moles of NH₂/number of moles of NCO) in the obtained mixed solution of component A, component B, and component C is 0.9. Also, the content of microspheres (1), which are component C, relative to the entire mixed solution above, is 2.1% by weight.

### Example 3

A mixed solution of component A, component B, and component C was obtained in the same manner as in Example 1, except that 3.5 g of microspheres (4) was used instead of 3.5 g of microspheres (1), component C of Example 1.

Note that the ratio of the number of moles of NH₂ in MOCA of component B to the number of moles of NCO in prepolymer (1) of component A (number of moles of NH₂/number of moles of NCO) in the obtained mixed solution of component A, component B, and component C is 0.9. Also, the content of microspheres (4), which are component C, relative to the entire mixed solution above, is 2.7% by weight.

The obtained mixed solution of component A, component B, and component C was poured into a mold form (850 mm×850 mm square shape) that had been heated to 120° C. Heating and temperature rise were performed for a period of 2 to 15 minutes such that the average temperature rise rate in 2 to 5 minutes from the completion of the pouring was 6.9° C./min, and the temperature after 15 minutes from the completion of the pouring was set to 150° C. Thereafter, the temperature was maintained at 150° C. for 15 to 20 minutes from the completion of the pouring to perform primary curing. The relationship between time from the completion of the pouring and temperature in the primary curing is shown in FIG. 1. The formed resin foamed product was removed from the mold form and allowed to undergo secondary curing in an oven at 120° C. for 4 hours. The obtained resin foamed product was allowed to cool down to 25° C. and then heated again in an oven at 120° C. for 5 hours. The obtained resin foamed product was sliced into thickness of 1.3 mm over the thickness direction to produce a urethane sheet, and double-sided tape was attached to the back side of this urethane sheet to obtain a polishing pad.

### Comparative Example 1

A mixed solution of component A, component B, and component C was obtained in the same manner as in Example 1, except that 2.9 g of microspheres (2) was used instead of 3.5 g of microspheres (1), component C of Example 1.

Note that the ratio of the number of moles of NH₂ in MOCA of component B to the number of moles of NCO in prepolymer (1) of component A (number of moles of NH₂/number of moles of NCO) in the obtained mixed solution of component A, component B, and component C is 0.9. Also, the content of microspheres (2), which are component C, relative to the entire mixed solution above, is 2.2% by weight.

The obtained mixed solution of component A, component B, and component C was poured into a mold form (850 mm×850 mm square shape) that had been heated to 80° C. Heating and temperature rise were performed for a period of 2 to 15 minutes such that the average temperature rise rate in 2 to 5 minutes from the completion of the pouring was 8.0° C./min, and the temperature after 15 minutes from the completion of the pouring was set to 128° C. Thereafter, the temperature was maintained at 128° C. for 15 to 20 minutes from the completion of the pouring to perform primary curing. The relationship between time from the completion of the pouring and temperature in the primary curing is shown in FIG. 1. The formed resin foamed product was removed from the mold form and allowed to undergo secondary curing in an oven at 120° C. for 4 hours. The obtained resin foamed product was allowed to cool down to 25° C. and then heated again in an oven at 120° C. for 5 hours. The obtained resin foamed product was sliced into thickness of 1.3 mm over the thickness direction to produce a urethane sheet, and double-sided tape was attached to the back side of this urethane sheet to obtain a polishing pad.

### Comparative Example 2

A mixed solution of component A, component B, and component C was obtained in the same manner as in Comparative Example 1, except that 2.7 g of microspheres (3) was used instead of 2.9 g of microspheres (2), component C of Comparative Example 1.

Note that the ratio of the number of moles of NH₂ in MOCA of component B to the number of moles of NCO in prepolymer (1) of component A (number of moles of NH₂/number of moles of NCO) in the obtained mixed solution of component A, component B, and component C is 0.9. Also, the content of microspheres (3), which are component C, relative to the entire mixed solution above, is 2.1% by weight.

The obtained mixed solution of component A, component B, and component C was poured into a mold form (850 mm×850 mm square shape) that had been heated to 80° C. Heating and temperature rise were performed for a period of 2 to 15 minutes such that the average temperature rise rate in 2 to 5 minutes from the completion of the pouring was 7.6° C./min, and the temperature after 15 minutes from the completion of the pouring was set to 128° C. Thereafter, the temperature was maintained at 128° C. for 15 to 20 minutes from the completion of the pouring to perform primary curing. The relationship between time from the completion of the pouring and temperature in the primary curing is shown in FIG. 1. The formed resin foamed product was removed from the mold form and allowed to undergo secondary curing in an oven at 120° C. for 4 hours. The obtained resin foamed product was allowed to cool down to 25° C. and then heated again in an oven at 120° C. for 5 hours. The obtained resin foamed product was sliced into thickness of 1.3 mm over the thickness direction to create a urethane sheet, and double-sided tape was attached to the back side of this urethane sheet to obtain a polishing pad.

### Comparative Example 3

Production of a urethane sheet was attempted based on the same curing conditions as in Comparative Example 1 using the mixed solution of component A, component B, and component C obtained in Example 1, but component C was not expanded and open pores could not be confirmed. As a result, it was not possible to obtain an appropriate urethane sheet having open pores and a polishing pad, and therefore, the evaluation on the urethane sheet and polishing pad described below could not be performed for Comparative Example 3.

### (Evaluation Methods)

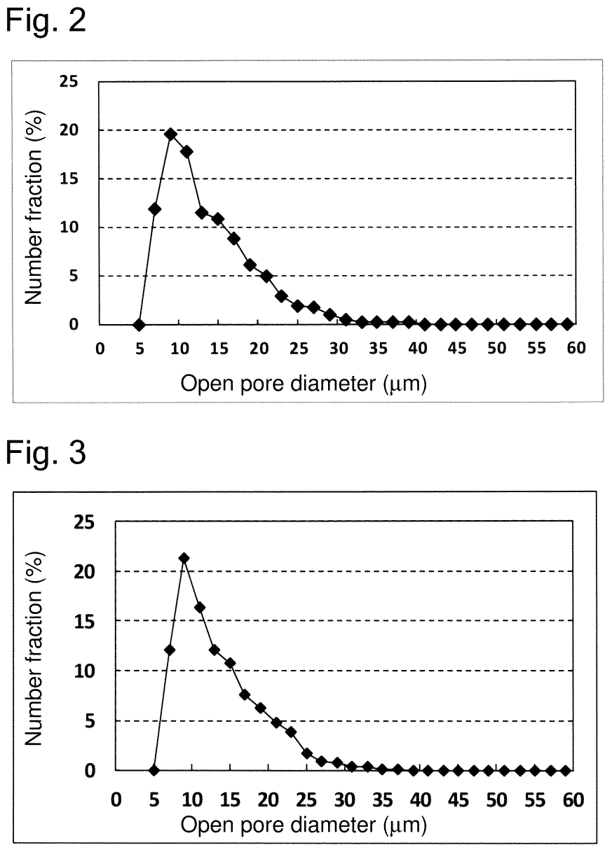

For each of the urethane sheets (in the state before attaching the double-sided tape) or polishing pads of Examples 1 to 3 and Comparative Examples 1 and 2, the following measurements or evaluations were carried out: (1) density and Shore D hardness, (2) average open pore diameter, open pore rate, number of open pores, and distribution curve, (3) scratches, and (4) polishing rate. The measurement results are shown in Tables 1 to 4 and FIGS. 2 to 11 below.

(1) Density and Shore D hardness

### (Density)

The density (g/cm³) of the urethane sheet was measured in accordance with the Japanese Industrial Standards (JIS K 6505).

### (Shore D Hardness)

The Shore D hardness of the urethane sheet was measured using a D-type hardness meter in accordance with the Japanese Industrial Standards (JIS-K-6253). Here, the measurement sample was obtained by stacking multiple urethane sheets as necessary such that the total thickness was at least 4.5 mm or more.

### (2) Average Open Pore Diameter, Open Pore Rate, Number of Open Pores, and Distribution Curve

Three regions (each a rectangle of 0.5 mm long×0.7 mm wide) were arbitrarily selected from the surface of the polishing layer of the polishing pad without bias, and each region was magnified by 400 times using a laser microscope (VK-X1000, manufactured by KEYENCE CORPORATION) for observation. Each of the obtained images (a rectangle of 0.5 mm long×0.7 mm wide) was subjected to a binarization treatment using image processing software (WinROOF2018 Ver4.0.2, manufactured by MITANI Corporation) to confirm the open pores, and the circular equivalent diameter (open pore diameter) was calculated from the area of each of the open pores. Note that the cutoff value (lower limit) of the open pore diameter was set to 5 μm and the noise component was excluded.
Average Open Pore Diameter

By averaging all open pore diameters included in each of the above regions (images), the average open pore diameter of each region was calculated. By further averaging the average open pore diameters of the three regions thus obtained, the final average open pore diameter was calculated.
Open Pore Rate

The proportion (%) of the total area of open pore portions per area of each of the above regions (images) (total area of open pore portions/area of image (region)×100) was calculated. By further averaging the open pore rates of the three regions thus obtained, the final open pore rate was calculated.
Number of Open Pores

The number of open pores per area of each of the above regions (images) (pores/mm²) was calculated. By further averaging the numbers of open pores of the three regions thus obtained, the final number of open pores was calculated.
Distribution Curve

For the open pore diameter calculated by the above-mentioned image observation in each of the above regions (images), an open pore diameter histogram was represented with a broken line, where every 2 μm range is represented by one class (for example, 15.0 μm or more and less than 17.0 μm, or the like). In the open pore diameter histogram, the proportion (number fraction) (%) of the number of open pores in each class relative to the total number of open pores in all classes (number of open pores in each class/total number of open pores in all classes×100) was calculated. Also, the open pore circumference in each class (the length of the circumference of the open pore) was calculated by multiplying the lowest value of the open pore diameter in each class (for example, 15.0 μm for the class of 15.0 μm or more and less than 17.0 μm) by the circular constant.

Then, a distribution curve of open pore diameter-number fraction and a distribution curve of open pore diameter-open pore circumference×number fraction in each region (image) were obtained.

By further averaging the respective distribution curves of open pore diameter-number fraction and distribution curves of open pore diameter-open pore circumference×number fraction of the three regions thus obtained, the final distribution curve of open pore diameter-number fraction and distribution curve of open pore diameter-open pore circumference×number fraction were obtained.

### (3) Scratches

For the evaluation of scratches, a substrate was polished using the polishing pad under the conditions described in the (Polishing test) below, and the substrate after the polishing processing was measured in the high sensitivity measurement mode of a wafer surface inspection apparatus (manufactured by KLA-Tencor Corporation, Surfscan SP5) to detect defects (surface defects) with a size of 110 nm or more on the entire substrate. For each of the detected defects, analysis of SEM images taken using a review SEM was carried out to classify them into “particles”, “pad debris”, and “scratches”, and the number of scratches among these was measured. The result is the average result at n4. Here, the category “particles” means residual fine particles that adhere to the surface of the workpiece to be polished, the category “pad debris” means debris of the polishing layer that adhere to the surface of the workpiece to be polished, and the category “scratches” means scratches on the surface of the workpiece to be polished.

### (Polishing Test)

Polishing machine used: F-REX300X (manufactured by EBARA CORPORATION)
Disk: A188 (manufactured by 3M Company)
Temperature of polishing agent: 20° C.
Rotation speed of polishing turn table: 85 rpm
Rotation speed of polishing head: 86 rpm
Polishing pressure: 3.5 psi
Polishing slurry (metal film): CSL-9044C (a mixed solution with a weight ratio of CSL-9044C undiluted solution: pure water=1:1 was used) (manufactured by Fujimi Corporation)
Flow rate of polishing slurry: 200 ml/min
Polishing time: 60 seconds
Workpiece to be polished (metal film): Cu film substrate (300 mm diameter disk-shaped)
Pad break: 35N 10 minutes
Conditioning: Ex-situ, 35N, 4 scans

### (4) Polishing Rate

For the polishing pad, the polishing rate on the workpiece polished based on the polishing conditions described in (3) (Polishing test) above was measured as follows.

For the Cu film substrate before and after the polishing test, measurements were performed in the diameter direction on the substrate, and the thicknesses before and after the polishing test were measured at those locations. Based on the measured thicknesses, the average value of the thicknesses before the polishing test and the average value of the thicknesses after the polishing test were calculated, and by taking the difference between these average values, the average value of the polished thicknesses was calculated. Then, the obtained average value of the polished thicknesses was used as the polishing rate per 60 seconds of polishing time. Note that the thickness measurement was conducted with a four point probe sheet resistance measuring apparatus (KLA-Tencor Corporation, trade name “RS-200”, measurement: DBS mode).

TABLE 1

| | Physical properties | | | | |
|---|---|---|---|---|---|
| | | Shore D | Average open | Open | Number of |
| | Density | hardness | pore diameter | pore | open pores |
| | g/cm³ | — | μm | rate | pores/mm² |
| Example 1 | 0.79 | 56 | 12.5 | 27 | 1872 |
| Example 2 | 0.85 | 59 | 12.4 | 24 | 1739 |
| Example 3 | 0.80 | 56 | 14.5 | 31 | 1631 |
| Comparative | 0.78 | 56 | 14.7 | 37 | 1549 |
| Example 1 | | | | | |
| Comparative | 0.79 | 56 | 15.5 | 35 | 1602 |
| Example 2 | | | | | |

TABLE 2

| | Scratches | Polishing rate |
|---|---|---|
| | (number) | (Å) |
| Example 1 | 6 | 8703 |
| Example 2 | 5 | 8175 |
| Example 3 | 8 | 8200 |
| Comparative | 11 | 8658 |
| Example 1 | | |
| Comparative | 14 | 8722 |
| Example 2 | | |

FIGS. 2 to 6 are graphs showing the respective distribution curves of open pore diameter-number fraction on the surface of the polishing layer of Examples 1 to 3 and Comparative Examples 1 and 2. FIGS. 7 to 11 are graphs showing the respective distribution curves of open pore diameter-open pore circumference×number fraction on the surface of the polishing layer of Examples 1 to 3 and Comparative Examples 1 and 2.

Each feature in each of the distribution curves in FIGS. 2 to 11 is shown in Tables 3 and 4.

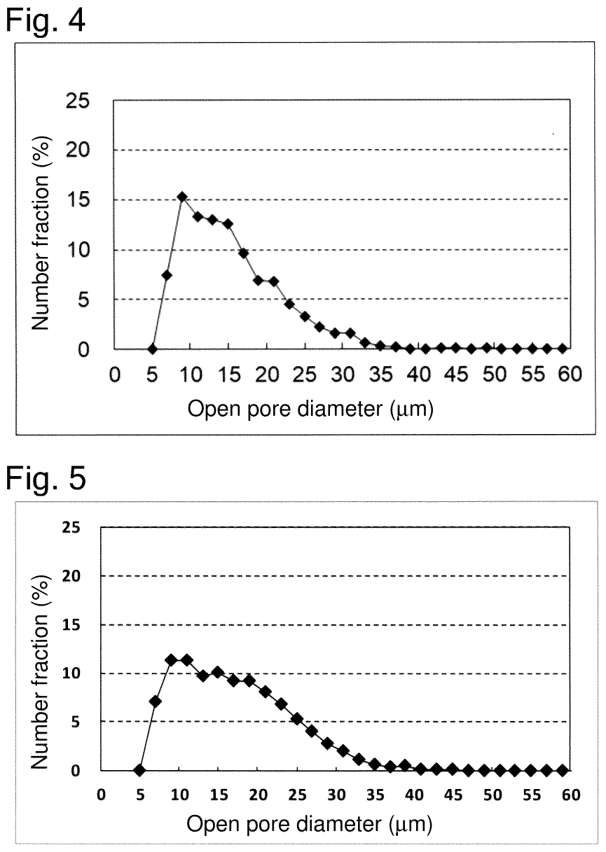

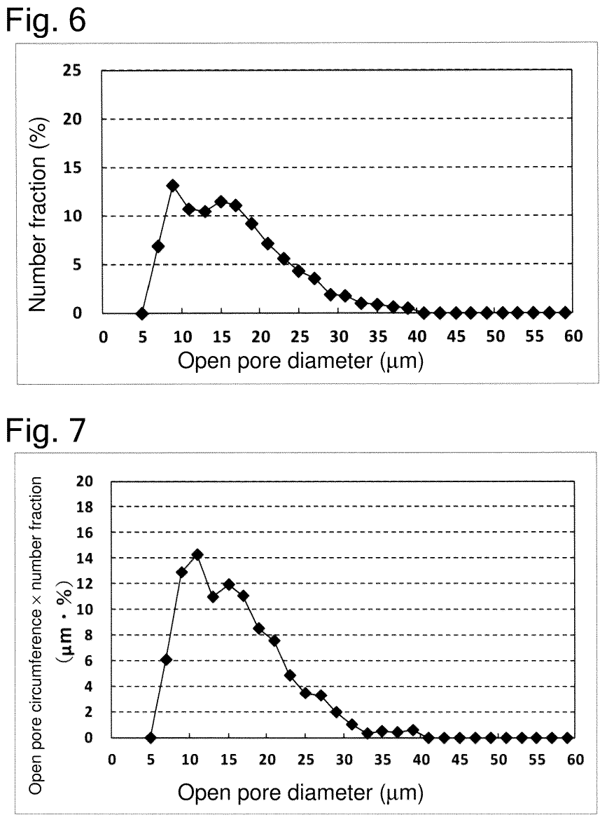

TABLE 3

| | | | | Comparative | Comparative |
|---|---|---|---|---|---|
| | Example 1 | Example 2 | Example 3 | Example 1 | Example 2 |
| | FIG. 2 | FIG. 3 | FIG. 4 | FIG. 5 | FIG. 6 |
| Open pore diameter at peak top (μm) | 9 | 9 | 9 | 11 | 9 |
| Number fraction at peak top (%) | 19.6 | 21.3 | 15.3 | 11.4 | 13.2 |
| Integrated value of number fraction in region | 71.2 | 72.5 | 61.0 | 49.5 | 52.0 |
| with open pore diameter of 15 μm or less (%) | | | | | |
| Integrated value of number fraction in region | 88.8 | 88.9 | 81.2 | 72.1 | 75.5 |
| with open pore diameter of 20 μm or less (%) | | | | | |

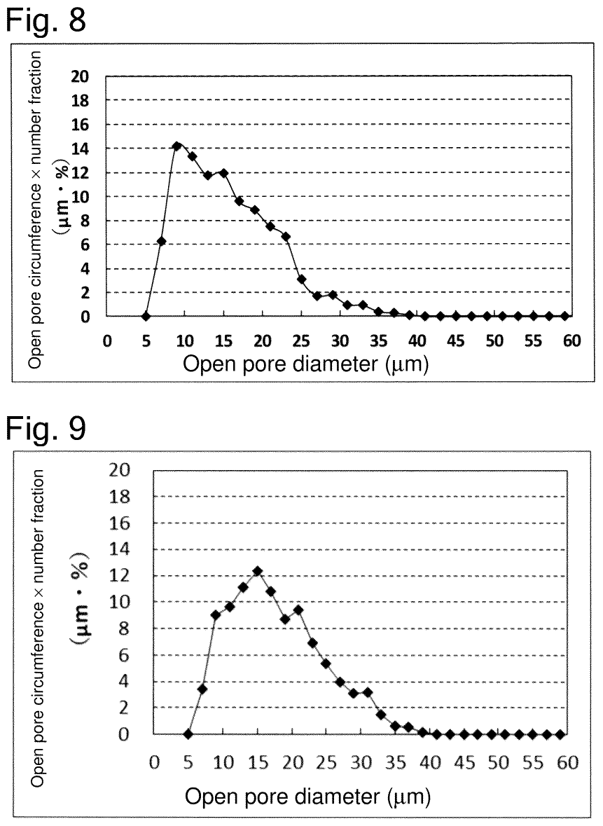

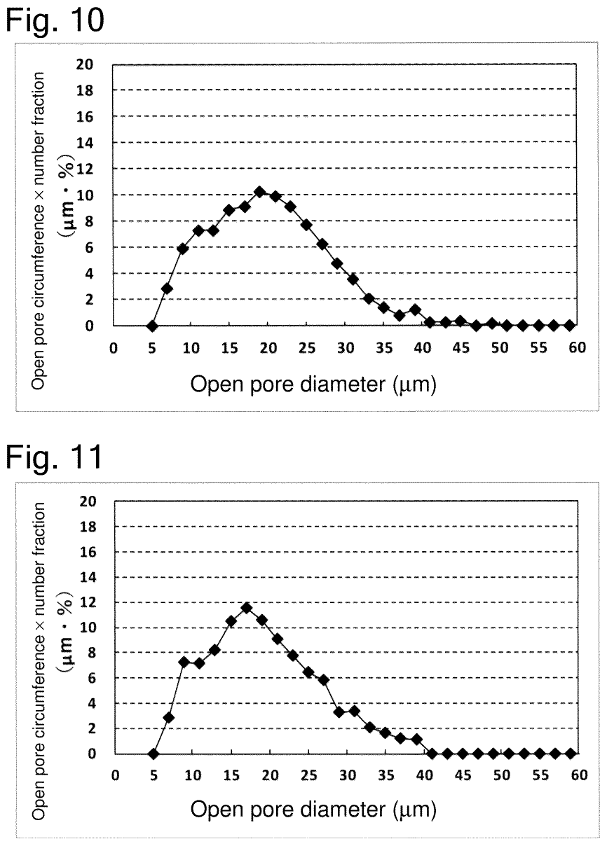

TABLE 4

| | | | | Comparative | Comparative |
|---|---|---|---|---|---|
| | Example 1 | Example 2 | Example 3 | Example 1 | Example 2 |
| | FIG. 7 | FIG. 8 | FIG. 9 | FIG. 10 | FIG. 11 |
| Open pore diameter at peak top (μm) | 11 | 9 | 15 | 19 | 17 |
| Open pore circumference × number fraction | 14.3 | 14.3 | 12.4 | 10.3 | 11.5 |
| at peak top (μm-%) | | | | | |
| Integrated value of open pore circumference × | 55.0 | 56.7 | 44.2 | 32.1 | 34.3 |
| number fraction in region with open pore | | | | | |
| diameter of 15 μm or less (%) | | | | | |
| Integrated value of open pore circumference × | 78.4 | 78.9 | 68.0 | 56.5 | 59.8 |
| number fraction in region with open pore | | | | | |
| diameter of 20 μm or less (%) | | | | | |

As can be seen from FIGS. 2 to 4 and 7 to 9, as well as Tables 3 and 4, the polishing pads of Examples 1 to 3 are polishing pads in which, in a number fraction-based distribution curve of open pore diameter on the surface of the polishing layer, a peak top is present in a region with an open pore diameter of 15 μm or less, and the number fraction of the open pores at the peak top is 15% or more. Also, the polishing pads of Examples 1 to 3 are polishing pads in which, in an open pore circumference×number fraction-based distribution curve of open pore diameter on the surface of the polishing layer, a peak top is present in a region with an open pore diameter of 15 μm or less.

On the other hand, as can be seen from FIGS. 5, 6, 10, and 11, as well as Tables 3 and 4, the polishing pads of Comparative Examples 1 and 2 are polishing pads in which, in a number fraction-based distribution curve of open pore diameter on the surface of the polishing layer, a peak top is present in a region with an open pore diameter of 15 μm or less, but the number fraction of the open pores at the peak top is less than 15%, and in which, in an open pore circumference×number fraction-based distribution curve of open pore diameter on the surface of the polishing layer, a peak top is present in a region with an open pore diameter of greater than 15 μm.

As can be seen from the results of Table 2, the polishing pads of Examples 1 to 3 exhibited sufficient polishing performance, with a small number of scratches, sufficient suppression of the occurrence of scratches, and a polishing rate of greater than 8000 A. On the other hand, the polishing pads of Comparative Examples 1 and 2 had a high polishing rate, but the number of scratches was large, indicating that they were not able to sufficiently suppress the occurrence of scratches compared to Examples 1 to 3.

From the above results, it was found that the occurrence of scratches can be suppressed by the polishing pad of the present invention, in which, in a number fraction-based distribution curve of open pore diameter on the surface of the polishing layer, a peak top is present in a region with an open pore diameter of 15 μm or less and the number fraction of the open pores at the peak top is 15% or less, or in which, in an open pore circumference×number fraction-based distribution curve of open pore diameter on the surface of the polishing layer, a peak top is present in a region with an open pore diameter of 15 μm or less.

1. A polishing pad having a polishing layer comprising microspheres,
wherein open pores are present on a surface of the polishing layer, and
in a number fraction-based distribution curve of open pore diameter on a surface of the polishing layer, a peak top is present in a region with an open pore diameter of 15 μm or less, and a number fraction of the open pores at the peak top is 15% or more.

2. A polishing pad having a polishing layer comprising microspheres,
wherein open pores are present on a surface of the polishing layer, and
in an open pore circumference×number fraction-based distribution curve of open pore diameter on a surface of the polishing layer, a peak top is present in a region with an open pore diameter of 15 μm or less.

3. The polishing pad according to claim 1, wherein a number fraction of the open pores at the peak top is 17% or more.

4. The polishing pad according to claim 1, wherein an average open pore diameter on a surface of the polishing layer is 5 to 20 μm.

5. The polishing pad according to claim 1, wherein the number of the open pores per unit area on a surface of the polishing layer is 1200 to 2500 pores/mm².

6. The polishing pad according to claim 1, wherein an open pore rate on a surface of the polishing layer is 10 to 50%.

7. The polishing pad according to claim 1, wherein the polishing layer further comprises a polyurethane resin.

8. The polishing pad according to claim 1, wherein the polyurethane resin is a cured product of a curable resin composition comprising an isocyanate-terminated urethane prepolymer, a curing agent, and thermoexpandable microspheres.

9. A method for producing a polishing pad having a polishing layer comprising microspheres, the method comprising:
(a) a step of preparing a curable resin composition comprising thermoexpandable microspheres with an average particle diameter (D50) of 1 to 20 μm; and
(b) a step of heating the curable resin composition under heating conditions including a temperature rise condition of 1.5 to 7.5° C./min to cure the curable resin composition, thereby forming the polishing layer, and to expand the thermoexpandable microspheres, thereby forming the microspheres.

10. The method for producing a polishing pad according to claim 9, wherein open pores are present on a surface of the polishing layer, and
in a number fraction-based distribution curve of open pore diameter on a surface of the polishing layer, a peak top is present in a region with an open pore diameter of 15 μm or less, and a number fraction of the open pores at the peak top is 15% or more.

11. A method for polishing a surface of an optical material or a semiconductor material, the method comprising a step of polishing a surface of an optical material or a semiconductor material using the polishing pad according to claim 1.

12. The polishing pad according to claim 2, wherein an average open pore diameter on a surface of the polishing layer is 5 to 20 μm.

13. The polishing pad according to claim 2, wherein the number of the open pores per unit area on a surface of the polishing layer is 1200 to 2500 pores/mm².

14. The polishing pad according to claim 2, wherein an open pore rate on a surface of the polishing layer is 10 to 50%.

15. The polishing pad according to claim 2, wherein the polishing layer further comprises a polyurethane resin.

16. The polishing pad according to claim 15, wherein the polyurethane resin is a cured product of a curable resin composition comprising an isocyanate-terminated urethane prepolymer, a curing agent, and thermoexpandable microspheres.

17. The method for producing a polishing pad according to claim 9,
wherein open pores are present on a surface of the polishing layer, and
in an open pore circumference×number fraction-based distribution curve of open pore diameter on a surface of the polishing layer, a peak top is present in a region with an open pore diameter of 15 μm or less.

18. A method for polishing a surface of an optical material or a semiconductor material, the method comprising a step of polishing a surface of an optical material or a semiconductor material using the polishing pad according to claim 2.
